(19) United States
(12) Patent Application Publication
(10) Pub. No.: US 2021/0191205 A1
(43) Pub. Date: Jun. 24, 2021

(54) ARRAY SUBSTRATE, METHOD FOR DRIVING SAME, DISPLAY MODULE AND DISPLAY DEVICE

(71) Applicants: Beijing BOE Optoelectronics Technology Co., Ltd., Beijing (CN); BOE Technology Group Co., Ltd., Beijing (CN)

(72) Inventors: Xiang Yuan, Beijing (CN); Chao Tian, Beijing (CN); Shuo Li, Beijing (CN); Qingqing Ma, Beijing (CN); Yinan Gao, Beijing (CN); Junpeng Han, Beijing (CN); Tianjiao Wang, Beijing (CN); Yin Yuan, Beijing (CN); Guojie Qin, Beijing (CN)

(73) Assignees: Beijing BOE Optoelectronics Technology Co., Ltd.; BOE Technology Group Co., Ltd.

(21) Appl. No.: 16/916,245

(22) Filed: Jun. 30, 2020

(30) Foreign Application Priority Data
Dec. 18, 2019 (CN) 201911308038.4

(51) Int. Cl. G02F 1/1362; G02F 1/1368; G09G 3/36; H01L 27/12

(52) U.S. Cl. CPC G02F 1/136286; H01L 27/124; G09G 3/3688; G02F 1/1368

(57) ABSTRACT

Disclosed are an array substrate, a method for driving the same, a display module, and a display device. The array substrate includes a plurality of data lines, a plurality of gate lines, a plurality of switch signal lines, and a plurality of pixels, wherein each of the pixels includes a switch circuit, a drive circuit, and a light-emitting element. Each of the switch signal lines may be connected to the switch circuits of the plurality of pixels disposed in at least one region, and each of the gate lines is connected to a plurality of rows of pixels disposed in different regions. Reliable scanning of the pixels row by row may be ensured by flexible control of signals provided by the signal lines. The array substrate needs to be disposed with fewer gate lines, such that the cost is reduced.

The present disclosure claims priority to Chinese Patent Application No. 201911308038.4, filed on Dec. 18, 2019 and entitled “ARRAY SUBSTRATE, METHOD FOR DRIVING SAME, DISPLAY MODULE AND DISPLAY DEVICE”, the entire contents of which are incorporated herein by reference.

### TECHNICAL FIELD

The present disclosure relates to the technical field of display, and in particular, relates to an array substrate, a method for driving the same, a display module, and a display device.

### BACKGROUND

Liquid crystal display (LCD) device is widely applied to the field of display due to the characteristics of small size, low power consumption, no radiation and the like.

In related arts, a plurality of gate lines extending in a first direction, a plurality of data lines extending in a second direction and a plurality of pixels disposed in an array are generally disposed on an array substrate in an LCD device, wherein the first direction is perpendicular to the second direction, each of the gate lines is connected to one row of pixels so as to provide a gate drive signal for the row of the pixels, and each of the data lines is connected to one column of pixels so as to provide a data signal for the column of the pixels.

### SUMMARY

Embodiments of the present disclosure provide an array substrate, a method for driving the same, a display module, and a display device. The technical solutions are as follows:

In one aspect, an array substrate is provided. The array substrate is provided with a plurality of regions and includes a plurality of data lines, a plurality of gate lines, a plurality of switch signal lines, and a plurality of pixels disposed in an array; wherein at least one row of the pixels are disposed in each of the regions, and each of the pixels includes a switch circuit, a drive circuit, and a light-emitting element, the switch circuit being connected to the drive circuit, and the drive circuit being connected to the light-emitting element; wherein

each of switch signal lines is connected to the switch circuits of the plurality of pixels disposed in at least one of the regions, and configured to provide a switch signal for the switch circuits connected to the switch signal line;

each of the data lines is connected to the switch circuits of one column of the pixels, and configured to provide a data signal for the switch circuits connected to the data line, and the switch circuit is configured to output the data signal to the drive circuit connected to the switch circuit in response to the switch signal; and

each of the gate lines is connected to the drive circuits of a plurality of rows of the pixels, at least two rows of the drive circuits connected to each of the gate lines are disposed in different regions, each of the gate lines is configured to provide a gate drive signal for the drive circuits connected to the gate line, and the drive circuit is configured to drive the light-emitting element connected to the drive circuit to emit light in response to the gate drive signal and the data signal.

Optionally, each of the switch signal lines is connected to the switch circuits of the plurality of pixels disposed in one of the regions, and the switch circuits connected to each of the switch signal lines are disposed in different regions.

Optionally, a plurality of rows of drive circuits connected to each of the gate lines are all disposed in different regions.

Optionally, the array substrate includes n gate lines, and n rows of the pixels are disposed in each of the regions;

wherein an i^{th} gate line is connected to drive circuits of an i^{th} row of pixels in each of the regions, n being a positive integer greater than 1, and i being a positive integer smaller than or equal to n.

Optionally, the drive circuit includes a drive transistor;

wherein a gate of the drive transistor is connected to the gate line, a first electrode of the drive transistor is connected to the switch circuit, and a second electrode of the drive transistor is connected to the light-emitting element.

Optionally, the switch circuit includes a switch transistor;

wherein a gate of the switch transistor is connected to the switch signal line, a first electrode of the switch transistor is connected to the data line, and a second electrode of the switch transistor is connected to the drive circuit.

Optionally, the switch circuit includes two switch transistors;

wherein gates of the two switch transistors are both connected to the switch signal line, a first electrode of one of the switch transistors is connected to the data line, a second electrode is connected to a first electrode of the other switch transistor, and a second electrode of the other switch transistor is connected to the drive circuit.

Optionally, the switch circuit includes two switch transistors; wherein

a gate of one of the switch transistors is connected to the switch signal line, a first electrode of one of the switch transistors is connected to a gate of the other switch transistor, and a second electrode of one of the switch transistors is connected to the drive circuit; and

a gate of the other switch transistor is connected to the data line, and a second electrode of the other switch transistor is connected to the drive circuit.

Optionally, the number of columns of a plurality of pixels disposed in an array included in the array substrate is less than the number of rows.

Optionally, each of the gate lines includes a first sub-line segment and a plurality of second sub-line segments connected to the first sub-line segment, each of the second sub-line segments being connected to drive circuits of one row of the pixels; and each of switch signal lines includes a third sub-line segment and a plurality of fourth sub-line segments connected to the third sub-line segment, each of the fourth sub-line segments is connected to the switch circuits of one row of the pixels;

wherein each of the first sub-line segments and each of the sub-line segments are parallel to each other, each of the second sub-line segments and each of the fourth sub-line segments are parallel to each other, and an extension direction of each of the first sub-line segments intersects an extension direction of any one of the second sub-line segments.

Optionally, each of the first sub-line segments and each of the third sub-line segments are both parallel to an extension direction of the data line; and

Each of the second sub-line segments and each of the fourth sub-line segment are both perpendicular to the extension directions of the data line.

Optionally, the number of columns of a plurality of pixels disposed in an array included in the array substrate is less than the number of rows, each of the switch signal lines is connected to the switch circuits of the plurality of pixels disposed in one of the regions, the switch circuits connected to each of the switch signal lines are disposed in different regions, the drive circuit includes a drive transistor, and the switch circuit includes a switch transistor; wherein

a gate of the drive transistor is connected to the gate line, a first electrode of the drive transistor is connected to the switch circuit, and a second electrode of the drive transistor is connected to the light-emitting element; and

a gate of the switch transistor is connected to the switch signal line, a first electrode of the switch transistor is connected to the data line, and a second electrode of the switch transistor is connected to the drive circuit.

In another aspect, a method for driving an array substrate is provided. The method is applicable to the array substrate and involves a plurality of drive periods in numbers same as switch signal lines. The method includes:

providing a data signal for each of the data lines in each of the drive periods;

providing a switch signal for one of the switch signal lines;

sequentially providing a gate drive signal for a plurality of gate lines;

outputting, by a switch circuit connected to the switch signal line, the data signal to a drive circuit connected to the switch circuit in response to the switch signal; and

driving, by the drive circuit, the light-emitting element connected to the drive circuit to emit light in response to the gate drive signals and the data signal;

wherein the switch signal is provided for different switch signal lines in different drive periods.

Optionally, providing the switch signal for one of the switch signal lines includes: continuously providing the switch signal at a first potential for one of the switch signal lines in each of the drive periods.

Optionally, each of the drive periods includes a plurality of sub-drive phases at intervals having the numbers same as gate lines included in the array substrate; and providing a switch signal for one of the switch signal lines includes:

providing the switch signal at the first potential for one of the switch signal lines in each of the sub-drive phases, and providing a switch signal at a second potential for one of the switch signal lines within an internal time frame of each two adjacent sub-drive phases;

sequentially providing gate drive signals for a plurality of gate lines includes:

providing the gate drive signals for one of the gate lines in each of the sub-drive phase, and providing the gate drive signals for different gate lines in different sub-drive phases.

In yet another aspect, the present disclosure provides a display module. The display module includes a gate drive circuit, a source drive circuit, a control circuit, and the above-mentioned array substrate; wherein

the gate drive circuit is connected to the gate lines in the array substrate and configured to provide the gate drive signal for the gate lines;

the source drive circuit is connected to the data lines in the array substrate and configured to provide providing the data signals for the data lines; and

the control circuit is connected to the switch signal lines in the array substrate and configured to provide the switch signals for the switch signal lines.

In yet still another aspect, a display device is provided. The display device includes the above-mentioned display module and a housing configured to provide packaging the display module.

### BRIEF DESCRIPTION OF DRAWINGS

For clearer descriptions of the technical solutions of the embodiments of the present disclosure, the accompanying drawings required to describe the embodiments are briefly described below. Apparently, the accompanying drawings described below are only some embodiments of the present disclosure. Those of ordinary skill in the art may further derive other accompanying drawings based on these accompanying drawings without inventive effort.

FIG. 1 is a schematic structural diagram of an array substrate according to an embodiment of the present disclosure;

FIG. 2 is a schematic structural diagram of another array substrate according to an embodiment of the present disclosure;

FIG. 3 is a schematic structural diagram of still another array substrate according to an embodiment of the present disclosure;

FIG. 4 is a schematic structural diagram of a pixel according to an embodiment of the present disclosure;

FIG. 5 is a schematic structural diagram of another pixel according to an embodiment of the present disclosure;

FIG. 6 is a schematic diagram of a method for driving an array substrate according to an embodiment of the present disclosure;

FIG. 7 is a sequence chart of a signal line in an array substrate according to the embodiment of the present disclosure;

FIG. 8 is a sequence chart of a signal line in another array substrate according to an embodiment of the present disclosure.

FIG. 9 is a schematic structural diagram of a display module according to an embodiment of the present disclosure.

### DETAILED DESCRIPTION OF EMBODIMENTS

For clearer descriptions of the objectives, technical solutions, and advantages of the present disclosure, further detailed description will be made below with reference to the accompanying drawings.

Transistors adopted in all embodiments of the present disclosure may be thin film transistors or field-effect transistors or other devices with the same characteristics, and the transistors adopted in the embodiment of the present disclosure are mainly switch transistors according to the effect in the circuit. Sources and drains of the switch transistors adopted herein are symmetrical, and thus the sources and the drains may be interchanged. In the embodiment of the present disclosure, the sources are named with the first electrodes, and the drains are named with the second electrodes. According to the forms in the accompanying drawings, the intermediate end of the transistor is a gate, the signal input end is a source, and the signal output end is a drain. In addition, the switch transistor adopted in the embodiment of the present disclosure may be any one of a P-type switch transistor and an N-type switch transistor, the P-type switch transistor is conducted when the gate is at a low potential and cut off when the gate is at a high potential, and the N-type switch transistor is conducted when the gate is at the high potential and cut off when the gate is at the low potential.

In related arts, a gate line needs to be disposed on the array substrate for each row of pixels. More gate lines need to be disposed on the array substrate when the resolution of the display device is higher, thus, more gate driving integrated circuits (ICs) for providing signals for gate lines need to be disposed, and the cost is higher.

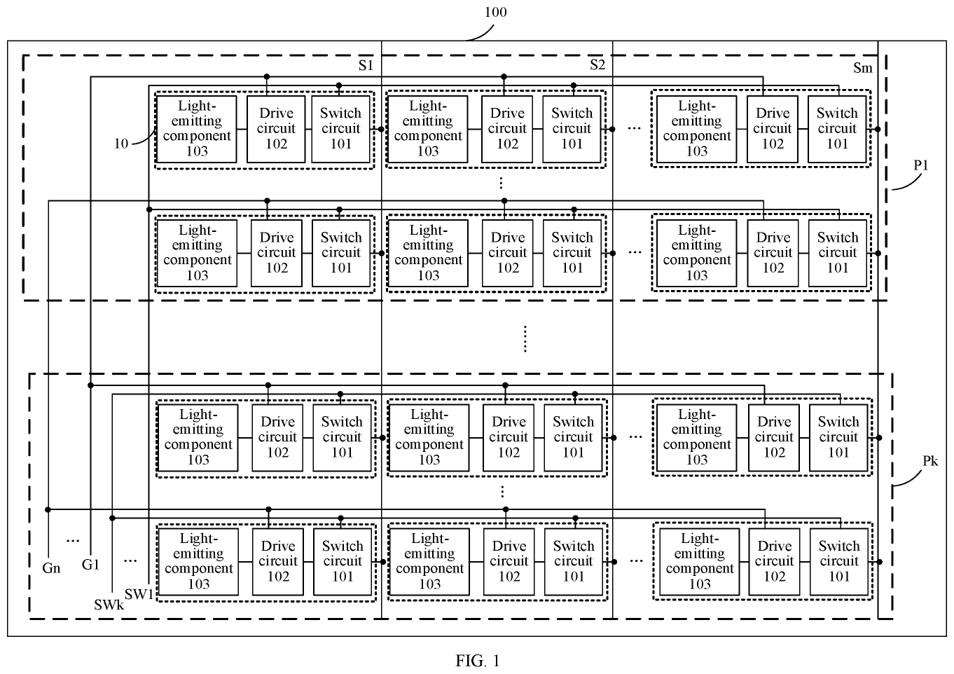

FIG. 1 is a schematic structural diagram of an array substrate according to an embodiment of the present disclosure. As shown in FIG. 1, the array substrate 100 may be provided with a plurality of regions P. The array substrate 100 may comprise a plurality of data lines S, a plurality of gate lines G, a plurality of switch signal lines SW and a plurality of pixels 10 disposed in an array. At least one row of pixels 10 are disposed in each of the regions P. Each of the pixels 10 may comprise a switch circuit 101, a drive circuit 102 and a light-emitting element 103. The switch circuit 101 may be connected to the drive circuit 102, and the drive circuit 102 may be connected to the light-emitting element 103.

For example, referring to FIG. 1, the array substrate 100 is provided with k regions from a region P1 to a region Pk, and the shown array substrate 100 comprises m data lines S1 to Sm, n gate lines G1 to Gn, k switch signal lines SW1 to SWk and pixels 10 in n rows and m columns disposed in the array and in each of the regions P, and k, m and n are all positive integers greater than 1.

Each of the switch signal lines SW may be connected to the switch circuits 101 of the plurality of pixels 10 disposed in at least one region P. Each of the switch signal lines SW may provide a switch signal for the switch circuits 101 connected to the switch signal line SW.

Each of the data lines S may be connected to the switch circuits 101 of one column of pixels 10. Each of the data lines S may provide a data signal for the switch circuits 101 connected to the data line S. The switch circuit 101 may output the data signals to the drive circuit 102 connected to the switch circuit in response to the switch signals.

For example, the switch circuit 101 may output the data signals provided by the data lines S to the drive circuit 102 connected to the switch circuit 101 when the switch signal lines SW provide the switch signals for the switch circuits 101.

Each of the gate lines G may be connected to the drive circuits 102 of a plurality of rows of pixels 10, and at least two rows of drive circuits connected to each of the gate lines G may be disposed in different areas P. Each of the gate lines G may provide a gate drive signal for the drive circuits 102 connected to the gate line G. The drive circuit 102 may drive the light-emitting element 103 connected to the drive circuit 102 to emit light in response to the gate drive signals and the data signals.

For example, the drive circuit 102 may output the data signal to the light-emitting element 103 connected to the drive circuit 102 so as to drive the light-emitting element 103 to emit light when the gate line G provides the gate drive signals for the drive circuit 102 and the switch circuit 101 outputs the data signals to the drive circuit 102.

In conclusion, the embodiment of the present disclosure provides the array substrate, wherein each of the switch signal lines may be connected to the switch circuits of the plurality of pixels disposed in at least one region, each of the switch circuits may output the data signal to the drive circuit connected to the switch circuit in response to the switch signal provided by the switch signal line, and thus, a gate line may be connected to a plurality of rows of pixels disposed in different regions. Compared with the related arts in which a gate line is disposed for each row of pixels, the method provided by the embodiment of the present disclosure has the advantage that reliable scanning of pixels row by row may be ensured by flexible control of the signals provided by the signal lines. The array substrate needs to be disposed with less amount of gate lines and also needs to be disposed with less amount of gate driving ICs, such that the cost is relatively low.

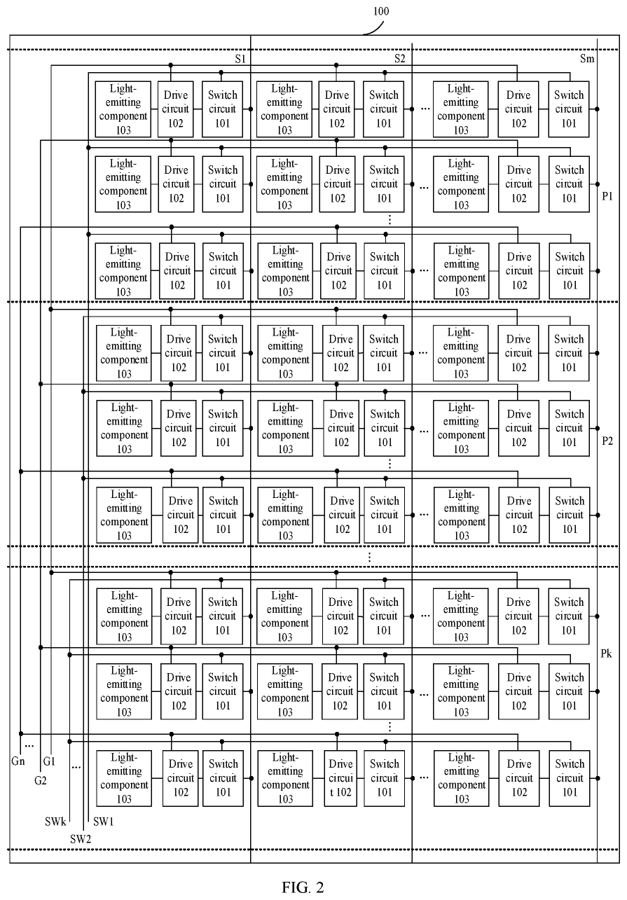

FIG. 2 is a schematic structural diagram of another array substrate according to an embodiment of the present disclosure. As shown in FIG. 2, each of the switch signal lines SW may be connected to the switch circuits 101 of the plurality of pixels 10 disposed in one of the regions, and the switch circuits 101 connected to each of the switch signal lines SW are disposed in different regions P.

For example, referring to FIG. 2, the array substrate 100 is provided with k regions from a region P1 to a region Pk, and k is a positive integer greater than 1. Correspondingly, the array substrate 100 may include k switch signal lines SW1 to SWk, wherein a first switch signal line SW1 may be connected to switch circuits 101 of a plurality of pixels disposed in a first region P1, a second switch signal line SW2 may be connected to switch circuits 101 of a plurality of pixels 10 disposed in a second region P2, and similarly, a k^{th} switch signal line SWk may be connected to switch circuits 101 of a plurality of pixels 10 disposed in a k^{th} region Pk.

By enabling each of the switch signal lines SW to be only connected to the switch circuits 101 of the plurality of pixels 10 disposed in one of the regions P, each of the switch signal lines SW only separately controls operating conditions of the plurality of pixels disposed in one of the regions P. In addition, by enabling each of the switch signal lines SW to be connected to the switch circuits 101 of the plurality of pixels 10 disposed in different regions P, thus, sequential scanning may be carried out on each of the regions by flexible control of the switch signal provided by each of the switch signal lines SW, and the display effect is ensured.

For example, the switch circuits 101 of the plurality of pixels 10 disposed in the k regions P may be sequentially started when switch signals are sequentially provided for the k switch signal lines SW1 to SWk, thereby enabling the plurality of pixels 10 disposed in the k regions P to sequentially emit light. Compared with the related arts in which a plurality of gate driving ICs are disposed to simultaneously drive the pixels disposed in the plurality of regions P, the display power consumption may be reduced by regional driving.

Optionally, referring to FIG. 2, a plurality of rows of drive circuits G 102 connected to each gate line G may be all disposed in different regions P, i.e., each gate line G may be connected to drive circuits 102 of a plurality of rows of pixels 10 disposed in different regions P, and the drive circuits 102 connected to each gate line G may be disposed in different rows. For example, it is assumed that each gate line G is connected to drive circuits 102 of one hundred rows of pixels 10, and the drive circuits 102 connected to one hundred rows of pixels 10 may be all disposed in different areas P.

By connecting each switch signal line SW to the switch circuits 101 of the plurality of pixels 10 disposed in one of the regions P and connecting each gate line G to drive circuits 102 of a plurality of rows of pixels 10 disposed in different division areas P, a plurality of rows of pixels disposed in the same region P may be further prevented from simultaneously emitting light by flexibly adjusting gate drive signals provided by the gate lines G, and the display effect may be further ensured.

Optionally, referring to FIG. 2, the array substrate 100 may include n gate lines G1 to Gn, wherein n rows of pixels may be disposed in each of the regions P. An i^{th} gate line Gi may be connected to drive circuits 102 of an i^{th} row of pixels 10 in each of the regions P, n is a positive integer greater than 1, and i is a positive integer smaller than or equal to n. Pixel rows between each two adjacent rows of pixels 10 connected to each of the gate lines G are a fixed value (n−1), i.e., (n−1) rows of pixels are spaced between each two adjacent rows of pixels 10 connected to each of the gate lines G.

For example, referring to FIG. 2, a first gate line G1 may be connected to drive circuits 102 of a first row of pixels 10 disposed in each of the regions P when i is equal to 1. A second gate line G2 may be connected to drive circuits 102 of a second row of pixels 10 disposed in each of the regions P when i is equal to 2, and similarly, an n^{th} gate line Gn may be connected to drive circuits 102 of an n^{th} row of pixels disposed in each of the regions P when i is equal to n.

By connecting the i^{th} gate line G to the drive circuits 102 of the i^{th} row of pixels 10 disposed in each of the regions P, the disposing of the gate lines G is facilitated, a plurality of rows of pixels 10 disposed in each of the regions P may sequentially emit light along an extension direction of the data line S, thereby further ensuring the display effect of the array substrate.

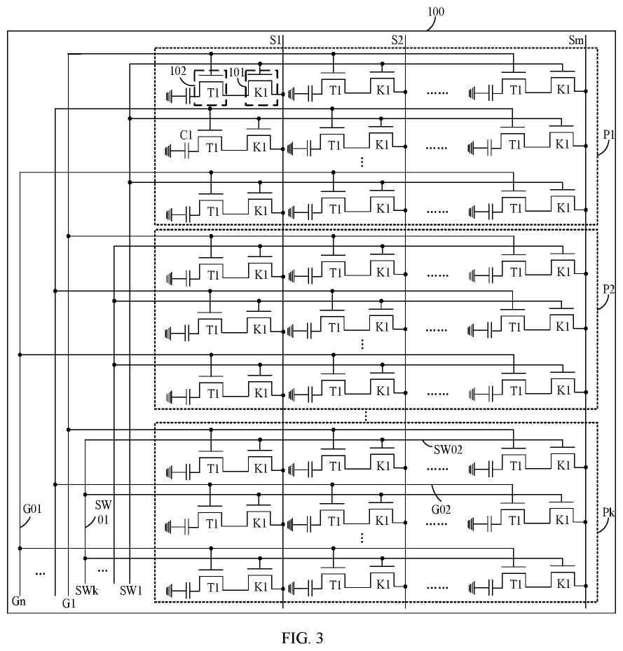

Optionally, the FIG. 3 is a schematic structural diagram of another array substrate according to an embodiment of the present disclosure. As shown in FIG. 3, the drive circuit 102 may include a drive transistor T1.

A gate of the drive transistor T1 may be connected to gate lines G, a first electrode of the drive transistor T1 may be connected to a switch circuit 101, and a second electrode of the drive transistor T1 may be connected to a light-emitting component 103 (not shown).

Optionally, the array substrate 100 may be an array substrate of an LCD display device or an organic light-emitting diode (OLED) display device.

Referring to FIG. 3, the light-emitting component 103 may include a pixel electrode, a common electrode and liquid crystal molecules disposed between the pixel electrode and the common electrode when the array substrate is the array substrate of the LCD display device. Referring to FIG. 3, the pixel electrode and the common electrode may be equivalent to a liquid crystal capacitor C1, and a storage capacitor (not shown) may be formed between wirings of the pixel electrode and the common electrode. The second electrode of the drive transistor T1 may be connected to the pixel electrode (i.e., one end of the liquid crystal capacitor C1) of the light-emitting component 103.

Optionally, referring to FIG. 3, the switch circuit 101 may include a switch transistor K1.

A gate of the switch transistor K1 may be connected to switch signal lines SW, a first electrode of the switch transistor K1 may be connected to data lines S, and a second electrode of the switch transistor K1 may be connected to the drive circuit 102. For example, referring to FIG. 3, the second electrode of the switch transistor K1 may be connected to the first electrode of the drive transistor T1. The light-emitting component 103 of the pixel provided by the embodiment of the present disclosure may emit light under driving of a gate drive signal and a data signal when the switch transistor K1 and the drive transistor T1 are simultaneously switched on.

Optionally, it is shown in conjunction with FIG. 2 and FIG. 3 that the shown array substrate 100 includes m data lines S1 to Sm. It should be noted that the switch circuit 101 provided by the embodiment of the invention include, only not limited to, a switch transistor K1, the switch circuit 101 may include two switch transistors K1 or more than two switch transistors K1, and the embodiment of the present disclosure is not limited to this. Taking the switch circuit 101 including two transistors K1 for example, schematic description is made on the pixel according to the embodiment of the present disclosure.

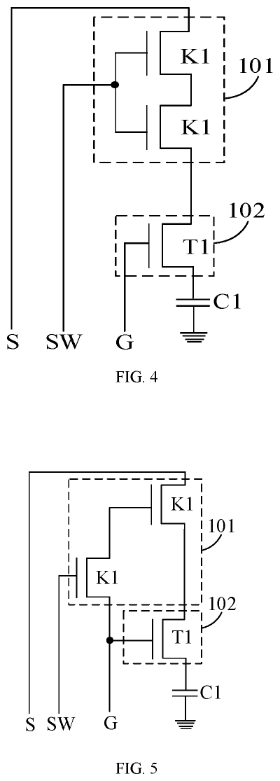

As an optional implementation, FIG. 4 is a schematic structural diagram of a pixel according to an embodiment of the present disclosure. As shown in FIG. 4, the switch circuit 101 may include two switch transistors K1.

Gates of the two switch transistors K1 may be both connected to switch signal lines SW, a first electrode of one of the switch transistors K1 may be connected to data lines S, and a second electrode may be connected to a first electrode of the other switch transistor K1. A second electrode of the other switch transistor K1 may be connected to a drive circuit 102. Referring to FIG. 4, a second electrode of the other switch transistor K1 is connected to a first electrode of a drive transistor T1.

As another optional implementation, FIG. 5 is a schematic structural diagram of another pixel according to an embodiment of the present disclosure. As shown in FIG. 5, the switch circuit 101 may include two switch transistors K1.

Agate of one of the switch transistors K1 may be connected to switch signal lines SW, a first electrode may be connected to a gate of the other switch transistor K1, and a second electrode may be connected to a drive circuit 102. Referring to FIG. 5, a second electrode of one of the switch transistors K1 may be connected to a gate of a drive transistor T1.

A first electrode of the other switch transistor K1 may be connected to data lines S, and a second electrode may be connected to the drive circuit 102. Referring to FIG. 5, a second electrode of the other switch transistor K1 may be connected to a first electrode of the drive transistor T1.

It should be noted that the number of columns of a plurality of pixels 10 disposed in an array included in the array substrate according to the embodiment of the present disclosure is less than the number of rows. It is assumed that the array substrate include pixels inn rows and m columns, wherein m is smaller than n. The array substrate according to the embodiment of the present disclosure may be an elongate array substrate, and a plurality of regions P may be disposed along the column directions of a plurality of pixels 10.

The elongate array substrate may be an array substrate of a conventional LCD display device or a reflection-type LCD display device or a bistable display device. The array substrate according to the embodiment of the present disclosure is not limited to the elongate array substrate, i.e., the array substrate also may be a square array substrate, and the number of columns of pixels included in the array substrate may be equal to the number of rows of pixels.

Optionally, in conjunction with FIG. 2 and FIG. 3, each of the gate lines G may include a first sub-line segment G01 and a plurality of second sub-line segments G02 connected to the first sub-line segment G01, wherein each of the second sub-line segments G02 is connected to the drive circuits 102 of one row of pixels 10. Each of the switch signal lines SW may include a third sub-line segment SW01 and a plurality of fourth sub-line segments SW02 connected to the third sub-line segment SW01, wherein each of the fourth sub-line segments SW02 is connected to the switch circuits 101 of one row of pixels 10.

Each of the first sub-line segments G01 and each of the third sub-line segments SW01 are parallel to each other, each of the second sub-line segments G02 and each of the fourth sub-line segments SW02 are parallel to each other, and an extension direction of each of the first sub-line segments G01 intersects an extension direction of any one of the second sub-line segments G02.

For example, each of the first sub-line segments G01 and each of the third sub-line segments SW01 may be both parallel to an extension direction of the data line S. Each second sub-line segment G02 and each of the fourth sub-line segments SW02 may be both perpendicular to the extension direction of the data line S.

It is assumed that the array substrate 100 is provided with k regions, n rows of pixels are included in each of the k regions, and it may be determined that (k*n) gate lines need to be disposed in the array substrate in the related art to drive a plurality of rows of pixels 10 in the array substrate 100 when k is greater than 1 and n is greater than 2. In the array substrate according to the embodiment of the invention, reliable scanning of a plurality of rows of pixels 10 in the array substrate 100 may be realized only by disposing n gate lines. In other words, the array substrate according to the embodiment of the present disclosure needs to be disposed with less amount of gate lines, such that the number of gate lines need to be disposed may be reduced. Further, a circuit board such as a flexible printed circuit (FPC) is needed for the disposing of every gate driving IC, and thus, the array substrate according to the embodiment of the present disclosure needs to be disposed with less amount of FPCs. Materials required by the array substrate according to the embodiment of the present disclosure are relatively low in cost, such that the production cost is also low.

In conclusion, the embodiment of the present disclosure provides the array substrate, wherein each of the switch signal lines in the array substrate may be connected to the switch circuits of a plurality of pixels disposed in at least one region, each of the switch circuits may output the data signal to the drive circuit connected to the switch circuit in response to the switch signal provided by the switch signal line, and thus, a gate line may be connected to a plurality of rows of pixels disposed in different regions. Reliable scanning of pixels rows by rows may be ensured by flexible control of signals provided by the signal lines. The array substrate needs to be disposed with less amount of gate lines and further needs to be disposed with less amount of gate driving ICs, such that the cost is relatively low.

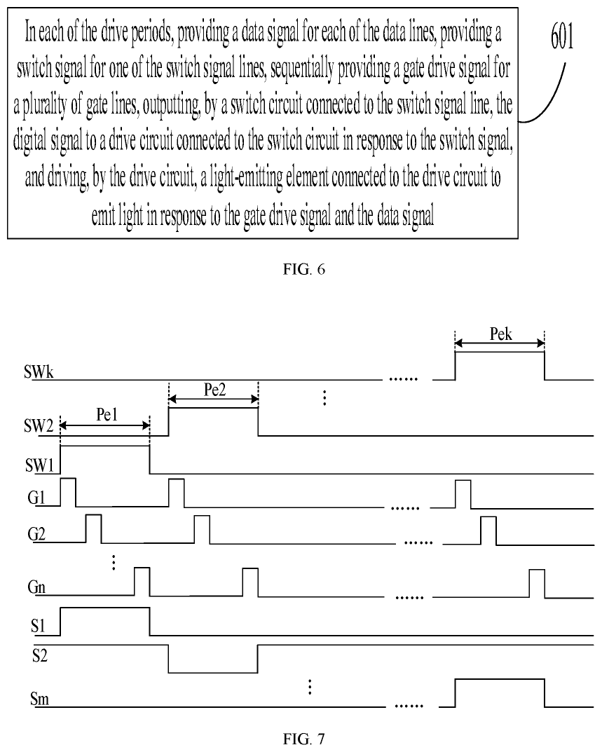

FIG. 6 is a flowchart of a method for driving an display substrate according to an embodiment of the present disclosure, and the method may be applied to the array substrates shown in any one of FIG. 1 to FIG. 3. As shown in FIG. 6, the method may involve a plurality of drive periods in numbers same as switch signal lines.

Step 601, a data signal is provided for each of the data lines in each of the drive periods, a switch signal is provided for one of the switch signal lines, a gate drive signal is sequentially provided for a plurality of gate lines, the data signal is output by a switch circuit connected to the switch signal line to a drive circuit connected to the switch circuit in response to the switch signal, and the light-emitting component connected to the drive circuit is driven by the drive circuit to emit light in response to the gate drive signal and the data signal.

Switch signals are provided for different switch signal lines in different drive periods, i.e., pixels disposed in different regions may be driven to emit light in different drive periods.

In conclusion, the embodiment of the present disclosure provides the method for driving the array substrate. Since the switch circuit may output the data signals provided by the data lines to a plurality of drive circuits connected to the switch circuit and disposed in at least one region in response to the switch signals provided by the switch signal lines, only one gate line may be connected to the drive circuits of a plurality of rows of pixels disposed in different regions, and reliable driving of a plurality of rows of pixels included in the array substrate may be realized by flexible control of signals provided by the signal lines. The array substrate needs to be disposed with less amount of gate lines and further needs to be disposed with less amount of gate driving ICs, such that the cost is relatively low.

As an optional implementation, the process of providing a switch signal for one of the switch signal lines, in step 601, may include:

continuously providing the switch signal at a first potential for one of the switch signal lines in each of the drive periods.

As another optional implementation, each of the drive periods may includea plurality of sub-drive phases at intervals having the numbers same as gate lines included in the array substrate. Correspondingly, the process of providing a switch signal for one of the switch signal lines, recorded in the step 601, may include:

providing the switch signal at a first potential for one of the switch signal lines at each of the sub-drive phases.

The method further includes: providing a signal at a second potential for one of the switch signal lines within an internal time frame of each two adjacent sub-drive phases, wherein the first potential is a valid potential, and the second potential is an invalid potential. Therefore, it should be also understood that the method include: stopping providing the switch signal for one of the switch signal lines within the internal time frame of each two adjacent sub-drive phases.

Correspondingly, the process of sequentially providing gate drive signals for a plurality of gate lines, recorded in the step 601, may include: providing the gate drive signals for one of the gate lines at each of the sub-drive phases, and providing the gate drive signals for different gate lines at different sub-drive phases.

In conjunction with FIG. 3, the pixel 10 emits light by joint control of the gate drive signal, the data signal and the switch signal, i.e., the switch signal line does not need to provide the switch signal when the gate line does not provide the gate drive signal, and the gate line does not need to provide the gate drive signal when the switch signal line does not provide the switch signal. Therefore, by adopting another optional implementation to provide signals for the gate lines and switch signal lines, i.e., simultaneously and respectively providing the signals for the switch signal lines and the gate lines in each of the drive periods and simultaneously stopping providing the signals for the switch signal lines and the gate lines, power loss caused by providing the switch signal for the switch signal lines when the gate drive signal is not provided for the gate line will be prevented.

Taking the array substrate shown in FIG. 3 for example, the drive transistor T1 and the switch transistor K1 are both N-type transistors, the first potential is higher than the second potential, and description is made on a driving principle of the array substrate according to the embodiment of the present disclosure.

As an optional implementation, FIG. 7 is a sequence chart of each signal line in an array substrate according to an embodiment of the present disclosure. The array substrate 100 includes k switch signal lines SW1 to SWk in total, and thus, referring to FIG. 7, the method for driving involves k drive periods Pe1 to Pek in total, and updating of a frame picture will be achieved by driving scanning of the k drive periods Pe1 to Pek. The frame picture is simultaneously displayed in one time from a view of a human eye due to short driving switching time of each of the drive periods.

Referring to FIG. 7, switch signals at a first potential may be sequentially provided for k switch signal lines SW1 to SWk in k drive periods Pe1 to Pek, while the switch signals at the first potential are continuously provided for only one of the switch signal lines SW in each of the drive periods Pe. Similarly, switch transistors K1 of a plurality of pixels 10 disposed in a first region P1 until the switch transistors K1 of a plurality of pixels 10 disposed in a k^{th} regions Pk may be sequentially switched on, and the switch transistors K1 of a plurality of pixels 10 disposed in the same region P may be simultaneously switched on. Data lines S1 to Sm may output data signals to a drive transistor T1 connected to each switch transistor K1 by a plurality of switch transistors K1 disposed in one of the regions P.

Further, referring to FIG. 7, gate drive signals may be sequentially provided for a first gate line G1 until an nth gate line Gn in a time when the switch signal at the first potential is provided for one of the switch signal lines SW. Similarly, the drive transistors T1 of n rows of pixels 10 disposed in the same region P may be switched on row by row, and the drive transistors K1 of m pixels 10 disposed in the same row may be simultaneously switched on. Data signals may charge a pixel electrode, connected to the drive transistor T1, by the switched-on drive transistor T1 to enable liquid crystal molecules to deflect and the pixels to emit light. In other words, the light-emitting component may emit light and display when the signals are simultaneously provided for the switch signal line SW and the gate line G to make the switch transistor K1 and the drive transistor T1 simultaneously switched on.

Exemplarily, taking the first drive period Pe1 for example, referring to FIG. 7, the switch signal at the first potential is only provided for a first switch signal line SW1 in the drive period Pe1, while the switch signals at the first potential are provided for the other switch signal lines SW. In this case, a plurality of switch transistors K1 disposed in the first region P1 are all switched on, whereas the switch transistors disposed in a second region P2 until the k^{th} region Pk are all switched off. The data lines S1 to Sm may output the data signals to the drive transistors T1 of the pixels 10 in n rows and m columns disposed in the first region P1 by a plurality of switch transistors K1 disposed in the first regions P1.

Further, gate drive signals at the first potential are sequentially provided for the first gate line G1 until the nth gate line Gn in the drive period Pe1. The drive transistors T1 of a first row of pixels 10 until the drive transistors T1 of an nth row of pixels in each of the regions P are switched on row by row. For example, the drive transistors T1 of m pixels 10 in the first row in each of the regions are switched on when the first gate line G1 provides the gate drive signal at the first potential. The data lines S1 to Sm only output the data signals to the plurality of drive transistors T1 disposed in the first region P1, at the same time, the data signals are output to pixel electrodes of a plurality of rows of pixels disposed in the first region P1 row by row only by the drive transistors T1 switched on row by row and disposed in the first region P1, thereby realizing row-by-row charging of n rows of pixels disposed in the first region P1.

The driving modes of other drive periods Pe may be referred to that of the first drive period Pe1, which is not repeated herein.

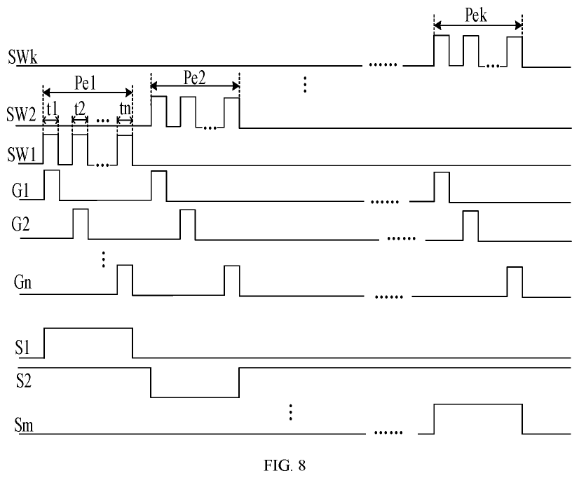

As another an optional implementation, FIG. 8 is a sequence chart of each of the signal lines in another array substrate according to an embodiment of the present disclosure. Referring to FIG. 8, since n gate lines G are contained, each of the drive periods Pe includes n sub-drive phases at intervals from t1 to tn (n sub-drive phases t1 to tn included in the drive period Pe1 are only shown in FIG. 8).

As shown in FIG. 8, a switch signal at a first potential is provided for one of the switch signal lines at sub-drive phases t1 to tn of each of the drive periods Pe. A signal at a second potential is provided for one of the switch signal lines within an internal time frame of each two adjacent sub-drive phases, while providing of the switch signal to the switch signal line is stopped. Therefore, switch transistors of a plurality of pixels 10 in each of the regions P are switched on at each of the sub-drive phases and are switched off within the interval time frame of each two adjacent sub-drive phases. Data lines S1 to Sm may output data signals to a drive transistor T1 connected to each of the switch transistors K1 by a plurality of switch transistors K1 disposed in one of the regions P.

Further, referring to FIG. 8, a gate drive signal at the first potential may be provided for one of gate lines at each of the sub-drive phases, and the gate drive signals at the first potential are provided for different gate lines at different sub-drive phases. In other words, the gate drive signals at the first potential are sequentially provided for n gate lines at the sub-drive phases t1 to tn. Similarly, at each of the sub-drive phases, the drive transistors T1 of one row of pixels 10 disposed in each of the regions P1 may be switched on, and the drive transistors T1 of n rows of pixels 10 disposed in one of the regions P may be switched on row by row. The data signals may charge a pixel electrode, connected to the drive transistor T1, by the switched-on drive transistor T1 to enable the liquid crystal molecules to deflect and the pixels to emit light. Like the driving mode shown in FIG. 7, the light-emitting component emits light and displays when the signals are simultaneously provided for switch signal lines SW and the gate lines G to make the switch transistor K1 and the drive transistor T1 simultaneously switched on.

Exemplarily, taking n sub-drive phases t1 to tn in a first drive period Pe1 for example, referring to FIG. 8, the switch signal at the first potential is provided for all the first switch signal lines SW at each of the sub-drive phases of the first drive period Pe1, and the signal at a second potential is provided for the a switch signal line within the internal time frame of each two adjacent sub-drive phases. The switch transistors K1 of a plurality of pixels 10 disposed in a first region P1 are switched on at each of the sub-drive phases and switched off within the interval time frame of each two adjacent sub-drive phases. Similarly, data lines S1 to Sm output data signals to the drive transistors T1 of the pixels 10 in n lines and m rows disposed in the first region P1 only at each of the sub-drive phases.

Further, gate drive signals at the first potential are sequentially provided for a first gate line G1 until an nth gate line Gn at the first sub-drive phase t1 until the nth sub-drive phase of the first drive period Pe1, the gate drive signals are provided for one of the gate lines at one of the sub-drive phases, thereby enabling the drive transistors T1 of a first row of pixels 10 until the drive transistors T1 of an nth row of pixels 10 disposed in each of the regions to be switched on row by row. The data lines S1 to Sm only output the data signals to a plurality of drive transistors T1 disposed in the first region P1, at the same time, the data signals are output to pixel electrodes of a plurality of pixels disposed in the first region P1 row by row only by the drive transistors T1 switched on row by row and disposed in the first region P1, thereby realizing row-by-row charging of the pixel electrodes of n rows of pixels disposed in the first division area P1.

The driving modes of other drive periods Pe may be referred to that of the first drive period Pe1, which is not repeated herein.

In conclusion, the embodiment of the present disclosure provides the method for driving the array substrate. The switch circuit may output the data signals provided by the data lines to the plurality of drive circuits connected to the switch circuit and disposed in at least one region in response to the switch signals provided by the switch signal lines, thus, only one gate line may be connected to the drive circuits of the plurality of rows of pixels disposed in different regions, and reliable driving of a plurality of rows of pixels included in the array substrate may be realized by flexible control of the signals provided by the signal lines. The array substrate needs to be disposed with less amount of gate lines and further needs to be disposed with less amount of gate driving ICs, such that the cost is relatively low.

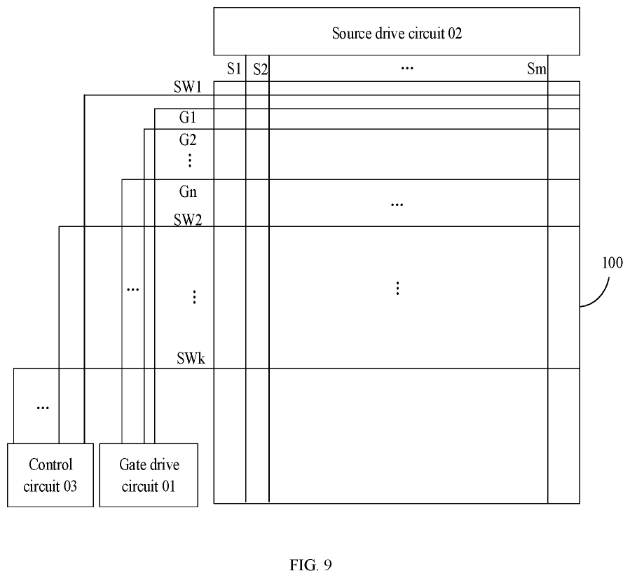

FIG. 9 is a schematic structural diagram of a display module according to an embodiment of the present disclosure. As shown in FIG. 9, the display module may include a gate drive circuit 01, a source drive circuit 02, a control circuit 03, and the array substrate according to the embodiment of the present disclosure. For example, the array substrate shown in any one of FIG. 1 to FIG. 3 may be included.

The gate drive circuit 01 may be connected to gate lines G in the array substrate 100 and configured to provide gate drive signal for the gate lines. The source drive circuit 02 may be connected to data lines S in the array substrate and configured to provide data signals for the data lines S. The control circuit 03 may be connected to switch signal lines SW in the array substrate 100 and configured to provide switch signals for the switch signal lines SW.

For example, referring to FIG. 9, the shown array substrate 100 includes n gate lines G1 to Gn, k switch signal lines SW1 to SWk and m data lines S1 to Sm in total. Referring to FIG. 9, the gate drive circuit 01 may be connected to the n gate lines G1 to Gn, the source drive circuit 02 may be connected to the m data lines S1 to Sm, and the control circuit 03 may be connected to the k switch signal lines SW1 to SWk.

Optionally, an embodiment of present disclosure provides a display device. The display device includes the display module shown in FIG. 9 and a housing configured to package the display module.

The display device may be any product or component having a display function such as the LCD display device, an OLED display device, an AMOLED display device, electronic paper, a mobile phone, a tablet PC, a television, a display, a notebook computer, a digital photo frame and navigator.

Those skilled in the art may clearly learned that, for convenience and brevity of description, the detailed working process of the array substrate and each circuit can be referred to the corresponding process in the foregoing method embodiment, and is not described herein again in this embodiment of the present disclosure.

The descriptions above are only optional embodiments of the present disclosure, but are not intended to limit the present disclosure; and any modifications, equivalent substitutions, improvements and the like made within the spirit and principles of the present disclosure are all intended to be concluded in the protection scope of the present disclosure.

What is claimed is:

1. An array substrate, provided with a plurality of regions, the array substrate comprising a plurality of data lines, a plurality of gate lines, a plurality of switch signal lines, and a plurality of pixels disposed in an array;
wherein at least one row of the pixels are disposed in each of the regions; and each of the pixels comprises a switch circuit, a drive circuit, and a light-emitting element, the switch circuit being connected to the drive circuit, and the drive circuit being connected to the light-emitting element; wherein
each of the switch signal lines is connected to the switch circuits of the plurality of pixels disposed in at least one of the regions, and configured to provide a switch signal for the switch circuits connected to the switch signal line;
each of the data lines is connected to the switch circuits of one column of the pixels, and configured to provide a data signal for the switch circuits connected to the data line, and the switch circuit is configured to output the data signal to a drive circuit connected to the switch circuit in response to the switch signal; and
each of the gate lines is connected to the drive circuits of a plurality of rows of the pixels, at least two rows of the drive circuits connected to each of the gate lines are disposed in different regions, each of the gate lines is configured to provide a gate drive signal for the drive circuits connected to the gate line, and the drive circuit is configured to drive the light-emitting element connected to the drive circuit to emit light in response to the gate drive signal and the data signal.

2. The array substrate according to claim 1, wherein each of the switch signal lines is connected to the switch circuits of the plurality of pixels disposed in one of the regions, and the switch circuits connected to each of the switch signal lines are disposed in different regions.

3. The array substrate according to claim 1, wherein a plurality of rows of drive circuits connected to each of gate lines are all disposed in different regions.

4. The array substrate according to claim 3, comprising n gate lines, and n rows of the pixels are disposed in each of the regions;
wherein an i^{th} gate line is connected to drive circuits of an i^{th} row of the pixels in each of the regions, n being a positive integer greater than 1, and i being a positive integer smaller than or equal to n.

5. The array substrate according to claim 1, wherein the drive circuit comprises a drive transistor;
wherein a gate of the drive transistor is connected to the gate line, a first electrode of the drive transistor is connected to the switch circuit, and a second electrode of the drive transistor is connected to the light-emitting element.

6. The array substrate according to claim 1, wherein the switch circuit comprises a switch transistor;
wherein a gate of the switch transistor is connected to the switch signal line, a first electrode of the switch transistor is connected to the data line, and a second electrode of the switch transistor is connected to the drive circuit.

7. The array substrate according to claim 1, wherein the switch circuit comprises two switch transistors;
wherein gates of the two switch transistors are both connected to the switch signal line, a first electrode of one of the switch transistors is connected to the data line, a second electrode is connected to a first electrode of the other switch transistor, and a second electrode of the other switch transistor is connected to the drive circuit.

8. The array substrate according to claim 1, wherein the switch circuit comprises two switch transistors; wherein
a gate of one of the switch transistors is connected to the switch signal line, a first electrode of one of the switch transistors is connected to a gate of the other switch transistor, and a second electrode of one of the switch transistors is connected to the drive circuit; and
a gate of the other switch transistor is connected to the data lines and a second electrode of the other switch transistor is connected to the drive circuit.

9. The array substrate according to claim 1, wherein the number of columns of a plurality of pixels disposed in an array included in the array substrate is less than the number of rows.

10. The array substrate according to claim 1, wherein each of the gate lines comprises a first sub-line segment and a plurality of second sub-line segments connected to the first sub-line segment, each of the second sub-line segments being connected to the drive circuits of one row of the pixels; and each of the switch signal lines comprises a third sub-line segment and a plurality of fourth sub-line segments connected to the third sub-line segment, each of the fourth sub-line segments being connected to the switch circuits of one row of the pixels;
wherein each of the first sub-line segments and each of the third sub-line segments are parallel to each other, each of the second sub-line segments and each of the fourth sub-line segments are parallel to each other, and an extension direction of each of the first sub-line segment intersects an extension direction of any one of the second sub-line segments.

11. The array substrate according to claim 10, wherein
each of the first sub-line segments and each of the third sub-line segments are both parallel to an extension direction of the data line; and
each of the second sub-line segments and each of the fourth sub-line segments are both perpendicular to the extension direction of the data line.

12. The array substrate according to claim 4, wherein the number of columns of a plurality of pixels disposed in an array included in the array substrate is less than the number of rows, each of the switch signal lines is connected to the switch circuits of the plurality of pixels disposed in one of the regions, the switch circuits connected to each of the switch signal lines are disposed in different regions, the drive circuit comprises a drive transistor, and the switch circuit comprises a switch transistor; wherein
a gate of the drive transistor is connected to the gate line, a first electrode of the drive transistor is connected to the switch circuit, and a second electrode of the drive transistor is connected to the light-emitting element; and
a gate of the switch transistor is connected to the switch signal line, a first electrode of the switch transistor is connected to the data line, and a second electrode of the switch transistor is connected to the drive circuit; wherein
each of the gate lines comprises a first sub-line segment and a plurality of second sub-line segments connected to the first sub-line segment, each of the second sub-line segments being connected to drive circuits of one row of the pixels; and each switch signal line comprises a third sub-line segment and a plurality of fourth sub-line segments connected to the third sub-line segment, each of fourth sub-line segments is connected to the switch circuits of one row of the pixels;
wherein each of the first sub-line segments and each of the third sub-line segments are parallel to each other and are both parallel to an extension direction of the data line, and each of the second sub-line segments and each of the fourth sub-line segments are parallel to each other and are both perpendicular to the extension line of the data line.

13. A method for driving an array substrate, the array substrate being provided with a plurality of regions, the array substrate comprising a plurality of data lines, a plurality of gate lines, a plurality of switch signal lines, and a plurality of pixels disposed in an array, at least one row of pixels being disposed in each of the regions;
wherein each of the pixels comprises a switch circuit, a drive circuit, and a light-emitting element, the switch circuit being connected to the drive circuit, and the drive circuit being connected to the light-emitting element; each of the switch signal lines is connected to the drive circuits of a plurality of pixels disposed in at least one region; each of the data lines is connected to the drive circuits of one row of the pixels, and each of the gate lines is connected to the drive circuits of a plurality of rows of the pixels, and at least two rows of the drive circuits connected to each of the gate lines are disposed in different regions;
the method involves a plurality of drive periods in numbers same as switch signal lines included in the array substrate, and comprises:
providing a data signal for each of the data lines in each of the drive periods;
providing a switch signal for one of the switch signal lines;
sequentially providing a gate drive signal for a plurality of gate lines;
outputting, by a switch circuit connected to the switch signal line, the data signal to a drive circuit connected to the switch circuit in response to the switch signal; and
driving, by the drive circuit, the light-emitting element connected to the drive circuit to emit light in response to the gate drive signal and the data signal;
wherein the switch signal is provided for different switch signal lines in different drive periods.

14. The method according to claim 13, wherein providing the switch signal for one of the switch signal lines comprises:
continuously providing a switch signal at a first potential for one of the switch signal lines in each of the drive periods.

15. The method according to claim 13, wherein
each of the drive periods comprises a plurality of sub-drive phases spaced apart from each other, the number of sub-drive phases being the same as the number of gate lines included in the array substrate;
providing the switch signal for one of the switch signal lines comprises:
providing the switch signal at a first potential for one of the switch signal lines in each of the sub-drive phases;
the method further comprises:
providing a signal at a second potential for one of the switch signal lines within an internal time frame of each two adjacent sub-drive phases; and
sequentially providing the gate drive signal for the plurality of gate lines comprises:
providing the gate drive signal for one of the gate lines in each of the sub-drive phases, and providing the gate drive signal for different gate lines in different sub-drive phases.

16. A display module, comprising a gate drive circuit, a source drive circuit, a control circuit, and an array substrate; wherein
the array substrate is provided with a plurality of regions and comprises a plurality of data lines, a plurality of gate lines, a plurality of switch signal lines, and a plurality of pixels disposed in an array, at least one row of pixels being disposed in each of the regions;
wherein each of the pixels comprises a switch circuit, a drive circuit, and a light-emitting element, the switch circuit being connected to the drive circuit, and the drive circuit being connected to the light-emitting element; each of the switch signal lines is connected to the switch circuits of the plurality of pixels disposed in at least one region and configured to provide a switch signal for the switch circuit connected to the switch signal line; each of the data lines is connected to the switch circuits of one row of the pixels and configured to provide a data signal for the switch circuit connected to the data line, and the switch circuit is configured to output the data signal to the drive circuit connected to the switch circuit in response to the switch signal; each of the gate lines is connected to the drive circuits of a plurality of rows of the pixels, and at least two rows of the drive circuits connected to each of the gate lines are disposed in different regions, each of the gate lines is configured to provide a gate drive signal for the drive circuit connected to the gate line, and the drive circuit is configured to drive the light-emitting element to emit light in response to the gate drive signal and the data signal;
the gate drive circuit is connected to the gate lines in the array substrate and configured to provide a gate drive signal for the gate lines;
the gate drive circuit is connected to the data lines in the array substrate and configured to provide a data signal for the data lines; and
the control circuit is connected to the switch signal lines in the array substrate and configured to provide a switch signal for the switch signal lines.

17. The display module according to claim 16, wherein each of the switch signal lines is connected to the switch circuits of the plurality of pixels disposed in one of the regions, and the switch circuits connected to each of the switch signal lines are disposed in different regions.

18. The display module according to claim 16, wherein the plurality of rows of drive circuits connected to each of the gate lines are all disposed in different regions.

19. The display module according to claim 18, wherein the array substrate comprises n gate lines, and n rows of pixels are disposed in each of the regions;
wherein an i^{th} gate line is connected to drive circuits of an i^{th} row of pixels in each of the regions, n being a positive integer greater than 1, and i being a positive integer smaller than or equal to n.

20. A display device, comprising the display module as defined in claim 16 and a housing configured to package the display module.
